(19) United States
(12) Patent Application Publication
(10) Pub. No.: US 2018/0292578 A1
(43) Pub. Date: Oct. 11, 2018

(54) SOLID-STATE IMAGING ELEMENT AND ELECTRONIC DEVICE

(71) Applicant: SONY SEMICONDUCTOR SOLUTIONS CORPORATION, Kanagawa (JP)

(72) Inventors: Masamitsu KAGEYAMA, Kanagawa (JP); Kazuya HAYASHIBE, Tokyo (JP); Hiroshi TANAKA, Kanagawa (JP)

(73) Assignee: SONY SEMICONDUCTOR SOLUTIONS CORPORATION, Kanagawa (JP)

(21) Appl. No.: 16/009,917

(22) Filed: Jun. 15, 2018

Related U.S. Application Data
(63) Continuation of application No. 15/305,721, filed on Oct. 21, 2016.

(30) Foreign Application Priority Data
May 9, 2014 (JP) 2014-097342

(51) Int. Cl. G02B 1/115; H04N 5/369; H01L 27/146; H01L 27/14; G02B 1/118; G02B 5/00; G02B 3/00; G02B 5/20

(52) U.S. Cl. CPC G02B 1/115; H04N 5/369; H01L 27/1462; G02B 5/201; G02B 1/118; G02B 5/003; G02B 3/0056; H01L 27/14

(57) ABSTRACT

The present disclosure relates to a solid-state imaging element and an electronic device capable of effectively inhibiting occurrence of reflection and diffraction of light on a light incident surface. A fine uneven structure including a recess and a protrusion is formed with a predetermined pitch on a light incident surface of a semiconductor layer in which photoelectric conversion sections are formed for a plurality of pixels; and an antireflective film is laminated on the fine uneven structure, the anti reflective film being formed with a film thickness different for each color of light received by each of the pixels. The pitch of one of the recess and protrusion formed in the fine uneven structure is generally identical in all the pixels, and is 100 nm or less. The present technology is applicable, for example, to a solid-state imaging element.

### TECHNICAL FIELD

The present disclosure relates to solid-state imaging elements and electronic devices, and in particular, to a solid-state imaging element and electronic device capable of effectively inhibiting occurrence of reflection and diffraction of light on a light incident surface.

### BACKGROUND ART

Generally, in a solid-state imaging device, such as a complementary metal oxide semiconductor (CMOS) image sensor and a charge coupled device (CCD), for example, photoelectric conversion elements are formed in a semiconductor substrate for a plurality of pixels, and light entering the semiconductor substrate undergoes photoelectric conversion. Then, a pixel signal in response to light quantity of the light received on each of the pixels is output, and an image of a subject. is constructed from the pixel signal.

Meanwhile, in a solid-state imaging element, light may be reflected on a light incident surface on which light enters the semiconductor substrate, and degradation in sensitivity and occurrence of stray light may cause degradation in image quality. Accordingly, conventionally in the solid-state imaging element, for example, a technology to achieve improvement in sensitivity and to prevent occurrence of stray light is used by using an antireflective film that uses multilayer film interference and by reducing reflection of light on the light incident surface of the semiconductor substrate.

In contrast, as a technology having more effective antireflective effect, for example, a structure in which a fine uneven structure is placed periodically, so-called moth-eye structure is known. Generally, an imprint technology is used to form such a moth-eye structure, and the moth-eye structure is applied to image sensors as well.

For example, as a structure for preventing reflection of incident light, Patent Literatures 1 to 3 disclosure solid-state imaging elements in which a fine uneven structure is formed on a light incident surface of a silicon layer in which photoelectric conversion elements are formed.

Meanwhile, conventionally, since an antireflective technology using the fine uneven structure uses a periodical structure, light may interact in accordance with a frequency (cycle) of the structure, and light may be transmitted through the light incident surface while being diffracted. Accordingly, the transmitted light that is diffracted on the light incident surface on which the fine uneven structure is formed causes a color mixture, and reflective light reflected on the light incident surface on which the fine uneven structure is formed becomes a new stray light source, which reduces image quality in some cases

Also, a technology to prevent reflection and improve conversion efficiency by providing the fine uneven structure on the light incident surface is often used in a el d of solar cell as well, and a random fine uneven structure is employed. However, in the solid-state imaging element, with a structure that employs the random fine uneven structure, variations occur in each pixel and scattered light or the like is generated, which also reduces image quality.

Also, although diffraction of light can be inhibited by causing the fine uneven structure formed on the light incident surface to have a high-frequency structure (a short-cycle structure), in order to obtain a sufficient effect of low reflection in the moth-eye structure, it is necessary to secure depth (height) of the structure to some extent. That is, in order to achieve both diffraction prevention and low reflection, it is preferable to make a high-aspect-ratio fine uneven structure. In particular, in an sensor, the light incident surface of a silicon layer, which is formed of a semiconductor or a metal, has a large difference in refractive index from an upper-layer film or air, and it is necessary to form, for example, a structure which is deeper (higher) than an interface between air and glass, etc., that is, a high-aspect-ratio structure.

However, it is disadvantageous to form such a high-aspect-ratio structure on the light incident surface of a silicon layer for laminating a film thereon, and implementation is difficult in terms of process difficulty and costs. Also, while the high-aspect-ratio structure itself is feasible by means of dry etching, in this case, an adverse influence of a damage or the like caused by plasma during treatment on photoelectric conversion characteristics of an element (increase in dark current and occurrence of white point) is a concern. In particular, a difference in the photoelectric conversion characteristics between a treated section and an untreated section causes variations or the like in a final image, leading to degradation in image quality.

In addition, use of wet etching with an alkali chemical or the like allows formation of the moth-eye structure while maintaining relatively slight treatment damage, and such treatment is performed in the solar cell field. However, since this method is a treatment method using crystal orientation, a shape that can be formed in this case has a constant aspect, height cannot be secured in a cycle short enough to prevent occurrence of diffraction, which fails to reduce much reflection.

### CITATION LIST

### Patent Document

Patent Document 1: JP 2013-33864 A

Patent Document 2: JP 2010-272612 A

Patent Document 3: JP 2006-147991 A.

### SUMMARY OF THE INVENTION

### Problems to be Solved by the Invention

As described above, conventionally, in the structure in which the moth-eye structure is applied to the solid-state imaging element, it is difficult to implement the fine uneven structure capable of achieving both prevention of diffraction and low reflection on the light incident surface.

The present disclosure has been made in view of such a situation, and an object of the present disclosure is to enable effective inhibition of occurrence of reflection and diffraction of light on the light incident surface.

### Solutions to Problems

A solid-state imaging element according to one aspect of the present disclosure includes: a fine uneven structure including a recess and a protrusion which are formed with a predetermined pitch on a light incident surface of a semiconductor layer in which photoelectric conversion sections are formed for a plurality of pixels; and an antireflective film laminated on the fine uneven structure, the antireflective film being formed with a film thickness different for each color of light received by each of the pixels.

An electronic device according to one aspect of the present disclosure includes a solid-state imaging element including: a fine uneven structure including a recess and a protrusion which are formed with a predetermined pitch on a light incident surface of a semiconductor layer in which photoelectric conversion sections are formed for a plurality of pixels; and an antireflective film laminated on the fine uneven structure, the antireflective film being formed film thickness different for each color of light received by each of the pixels.

In one aspect of the present disclosure, a fine uneven structure including a recess and a protrusion is formed with a predetermined pitch on a light incident surface of a semiconductor layer in which photoelectric conversion sections are formed for a plurality of pixels, and an antireflective film is laminated on the fine uneven structure, the antireflective film being formed with a film thickness different for each color of light received by each of the pixels.

### Effects of the Invention

According to one aspect of the present disclosure, occurrence of reflection and diffraction of light on the light incident surface can be effectively inhibited.

### BRIEF DESCRIPTION OF DRAWINGS

FIG. 1 is a block diagram illustrating an exemplary configuration of a first embodiment of a solid-state imaging element to which the present technology is applied.

FIG. 2 is a diagram illustrating an exemplary cross-sectional structure of the solid-state imaging element.

FIG. 3 is an enlarged view illustrating a light incident surface of a semiconductor substrate for each pixel.

FIG. 4 is a diagram illustrating transmission diffraction efficiency in an antireflective structure.

FIG. 5 is a diagram illustrating diffracted light.

FIG. 6 is a diagram illustrating a relationship between reflectance and wavelength.

FIG. 7 is a diagram illustrating the relationship between reflectance and wavelength.

FIG. 8 is a diagram illustrating the relationship between reflectance and wavelength.

FIG. 9 is a diagram illustrating an exemplary structure of a second embodiment of the solid-state imaging element to which the present technology is applied.

FIG. 10 is a block diagram illustrating an exemplary configuration of an imaging device mounted in an electronic device.

### MODE FOR CARRYING OUT THE INVENTION

Hereinafter, specific embodiments to which the present technology is applied will be described in detail with reference to the drawings.

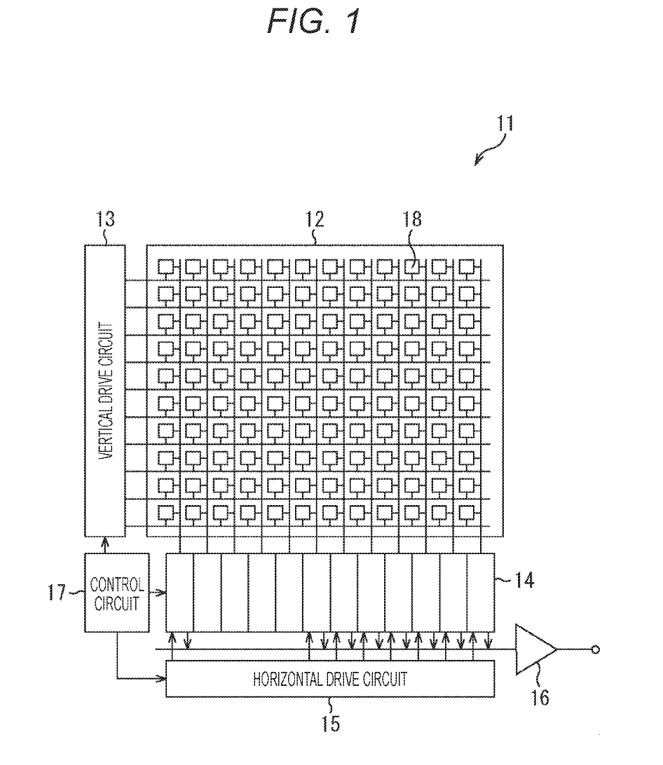

FIG. 1 is a block diagram illustrating an exemplary configuration of a first embodiment of a solid-state imaging element to which the present technology is applied.

In FIG. 1, a solid-state imaging element 11 includes a pixel region 12, a vertical drive circuit 13, column signal processing circuits 14, a horizontal drive circuit 15, an output circuit 16, and a control circuit 17.

The pixel region 12 includes a plurality of pixels 18 arranged in an array; each of the pixels 18 is connected to the vertical drive circuit 13 via a horizontal signal line, and connected to each of the column signal processing circuits 14 via a vertical signal line. The plurality of pixels 18 each output a pixel signal in response to light quantity of light applied via an unillustrated optical system, and from these pixel signals, an image of a subject focused on the pixel region 12 is constructed.

The vertical drive circuit 13 supplies, for each row of the plurality of pixels 18 arranged in the pixel region 12, a drive signal for driving (transferring, selecting, resetting, etc.) each pixel 18 to the pixel 18 via the horizontal signal line. The column signal processing circuit 14 performs analog-to-digital conversion on an image signal and removes reset noise by applying correlated double sampling (CDS) processing to the pixel signal that is output from each of the plurality of pixels 18 via the vertical signal line.

The horizontal drive circuit 15 supplies, to the column signal processing circuit 14, a drive signal for causing the column signal processing circuit 14 to output the pixel signal for each column of the plurality of pixels 18 arranged in the pixel region 12. The output circuit 16 amplifies the pixel signal supplied from the column signal processing circuit 14 at timing in response to the drive signal from the horizontal drive circuit 15, and then outputs the pixel signal to a downstream image processing circuit.

The control circuit 17 controls drive of each block within the solid-state imaging element 11. For example, the control circuit 17 generates a clock signal according to a driving cycle of each block, and supplies the clock signal to each block.

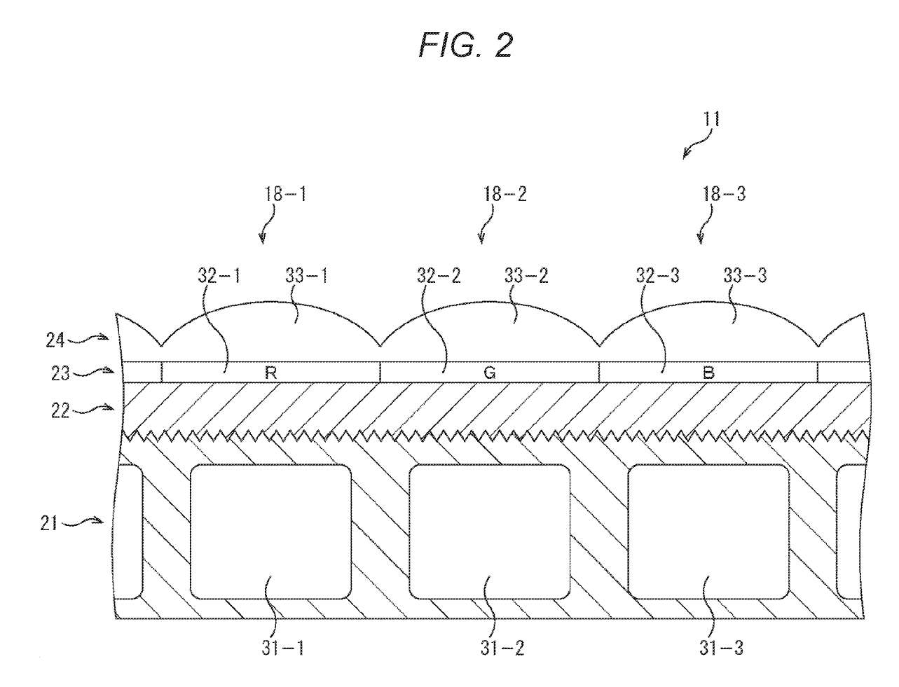

Next, FIG. 2 is a diagram illustrating a cross-sectional. exemplary structure of the solid-state imaging element 11.

As illustrated in FIG. 2, in the solid-state imaging element 11, a semiconductor substrate 21, an insulator film 22, a color filter layer 23, and an on-chip lens layer 24 are laminated, and FIG. 2 illustrates a cross-section of three pixels 18-1 to 18-3.

The semiconductor substrate 21 is, for example, a silicon wafer (Si) obtained by thinly slicing a single crystal of high purity silicon, and photoelectric conversion sections 31-1 to 31-3 that convert incident light into an electric charge by photoelectric conversion and accumulate the electric charge are formed in the pixels 18-1 to 18-3, respectively.

The insulator film 22 is formed, for example, by forming a film of a material that transmits light and has insulation properties, for example, silicon dioxide (SiO₂) The insulator film 22 insulates a surface of the semiconductor substrate 21.

In the color filter layer 23, filters 32 that transmit light of predetermined colors are arranged in respective pixels 18, and for example, the filters 32 that transmit light of three primary colors (red, green, and blue) are arranged. according to a so-called Bayer array. For example, as illustrated, the filter 32-1 that transmits light of red (R) is arranged in the pixel 18-1, the filter 32-2 that transmits light of green (G) is arranged in the pixel 18-2, and the filter 32-3 that transmits light of blue (B) is arranged in the pixel 18-3.

In the on-chip lens layer 24, on-chip lenses 33 that concentrate light in the photoelectric conversion sections 31 are arranged in respective pixels 18, and as illustrated, the on-chip lenses 33-1 to 33-3 are arranged in the pixels 18-1 to 18-3, respectively.

The solid-state imaging element 11 s structured in this way. Light that enters the solid-state imaging element 11 from an upper side of FIG. 2 is concentrated on the on-chip lens 33 in each pixel 18, and is then separated into each color by the filter 32. Then, in each pixel 18, light that is transmitted through the insulator film 22 and enters the semiconductor substrate 21 undergoes photoelectric conversion in the photoelectric conversion section 31. Here, a surface on a side on which light enters the solid-state imaging element 11 (an upper surface in FIG. 2) is hereinafter referred to as a light incident surface as needed. Also, an antireflective structure for preventing reflection of incident light that enters the semiconductor substrate 21 is formed on the light incident surface of the semiconductor substrate 21.

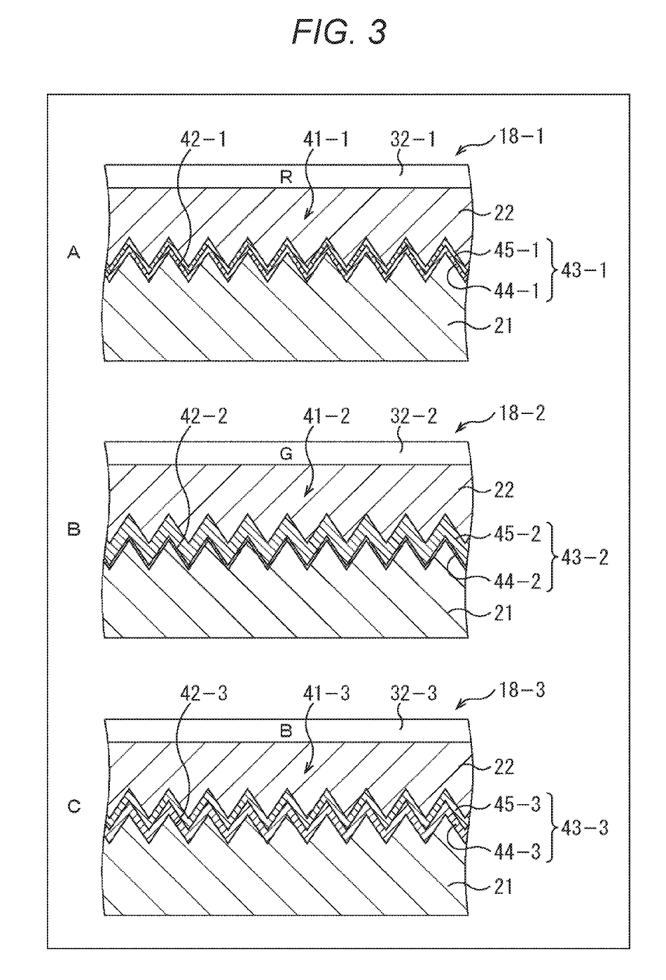

With reference to FIG. 3, the antireflective structure formed on the light incident surface of the semiconductor substrate 21 will be described.

A of FIG. 3 is an enlarged view of the light incident surface of the semiconductor substrate 21 of the pixel 18-1, B of FIG. 3 is an enlarged view of the light incident surface of the semiconductor substrate 21 of the pixel 18-2, and C of FIG. 3 is an enlarged view of the light incident surface of the semiconductor substrate 21 of the pixel 18-3.

As illustrated in FIG. 3, an antireflective structure 41 of the solid-state imaging element 11 includes a fine uneven structure 42 (so-called moth-eye structure) formed on the light incident surface of the semiconductor substrate 21, and a dielectric multilayer film 43 laminated on the fine uneven structure 41.

The fine uneven structure 42 has an uneven structure that includes a fine recess and protrusion which are each formed with a generally identical pitch and depth in the pixel 18-1, pixel 18-2, and pixel 18-3. For example, the fine uneven structure 42 is treated so that a recessed quadrangular pyramid shape is formed by using crystal anisotropy of the semiconductor substrate 21, and is formed so that the pitch of the uneven structure is 100 nm or less and a height of the uneven structure is 71 nm or less. Note that the pitch of the uneven structure may be 200 nm or less, for example, and is more preferably 100 nm or less.

Also, in plan view of the solid-state imaging element 11, the fine uneven structure 42 is formed in the pixel region 12 in which the pixels 18 are formed (FIG. 1). Also, in plan view of each pixel 18, the fine uneven structure 42 is formed in a region including at least a range in which the photoelectric conversion section 31 is provided. Note that by forming the fine uneven structure 42 by using crystal anisotropy of the semiconductor substrate 21, damage of treatment can be inhibited.

The dielectric multilayer film 43 is an antireflective film formed on the fine uneven structure 42 (light incident surface of the semiconductor substrate 21) so as to have structures each different in the pixel 18-1, the pixel 18-2, and the pixel 18-3, the antireflective film being for preventing reflection of the incident light. For example, a hafnium oxide film 44 and a tantalum oxide film 45, which have negative fixed electric charge, are laminated to form the dielectric multilayer film 43. Then, the dielectric multilayer film 43 is formed so that a film thickness differs for each pixel 18-1, pixel 18-2, and pixel 18-3, that is, for each color of light received by each pixel.

For example, the film thicknesses of the hafnium oxide film 44-1 and the tantalum oxide film 45-1 are determined so that the dielectric multilayer film 43-1 is structured to best prevent reflection of red light that is transmitted through the filter 32-1. Similarly, the film thicknesses of the hafnium oxide film 44-2 and the tantalum oxide film 45-2 are determined so that the dielectric multilayer film 43-2 is structured to best prevent reflection of green light that is transmitted through the filter 32-2. Also, the film thicknesses of the hafnium oxide film 44-3 and the tantalum oxide film 45-3 are determined so that the dielectric multilayer film 43-3 is structured to best prevent reflection of blue light that is transmitted through the filter 32-3. Note that these structures are determined by calculating an effective refractive-index distribution in a depth direction preferred to reduce reflectance under a constraint of the fine uneven structure 42 by using reflectance according to a desired wavelength band for each of the pixel 18-1, pixel 18-2 and pixel 18-3 as an evaluation function. For example, the film thicknesses of the hafnium oxide film 44 and the tantalum oxide film 45 are determined so that the films are each formed with a thickness of 5 to 100 nm.

Thus, the anti reflective structure 41 is formed in the solid-state imaging element 11 by forming the fine uneven structure 42 on the light incident surface of the semiconductor substrate 21 and by forming the dielectric multilayer film 43 with a film thickness of an appropriate interference condition for each col or received by the pixel 18. This enables effective inhibition of occurrence of reflection and diffraction of light on the light incident surface of the semiconductor substrate 21. Therefore, degradation in sensitivity, occurrence of a color mixture, and the tike caused by reflection or diffraction of light on the light incident surface of the semiconductor substrate 21 can be avoided, and degradation in image quality of an image captured by the solid-state imaging element 11 can be avoided.

Also, for example, as compared with a structure in which the dielectric multilayer film is laminated on a flatly formed light incident surface of the semiconductor substrate, the solid-state imaging element 11 allows about single-digit decrease of reflection of light on the light incident surface of the semiconductor substrate 21 (for example, inhibition of reflectance to about 1.16%). Furthermore, since the solid-state imaging element 11 has the fine uneven structure 42 with the pitch generally identical in all the pixels 18, for example, as compared with a structure in which the pitch of the fine uneven structure differs for each pixel (for example, the structure of the aforementioned Patent Literature 1), a process of treatment of the fine uneven structure 42 can be simplified.

Also, it is not necessary to form a high-aspect-ratio structure in the solid-state imaging element 11, and a feasible structure enables achievement of both diffraction prevention and low reflection. Furthermore, the solid-state imaging element 11 allows setting of the film thickness of the dielectric multilayer film 43 adaptively for the color of light received by the pixel 18, and thus allows achievement of spectrum improvement for each color.

Note that a shape of the protrusion (projection) that constitutes the fine uneven structure 42 may be, for example, a shape in which a cross-sectional shape in a surface which is orthogonal to the light incident surface of the semiconductor substrate 21 decreases or increases continuously toward inside from an incidence side, or discretely at several nanometers to tens of nanometers. That is, for example, as the shape of protrusion, a forward pyramid shape, an inverse pyramid shape, a bell shape, an inverse bell shape, and the like can be used. Also, for example, either one of a shape in which adjacent protrusions are in contact with each other, and a shape in which adjacent protrusions are not in contact with each other (a shape having a flat surface between the protrusions) may be used. Also, a cross-sectional shape of the protrusion in a surface parallel with the light incident surface of the semiconductor substrate 21 may be a rectangular shape, circular shape, or any other arbitrary shape, which allows effective antireflection.

Note that in addition to hafnium oxide (HfO₂) and tantalum oxide (Ta₂O₅), examples of material that can be used for a material that constitutes the dielectric multilayer film 43 include: silicon nitride (SiN), aluminum oxide (Al₂O₃), zirconium oxide (ZrO₂), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), and yttrium oxide (Y₂O₃). Also, a single-layer dielectric film may be used if the single-layer dielectric film has a function as an antireflective film in a similar manner to the dielectric multilayer film 43.

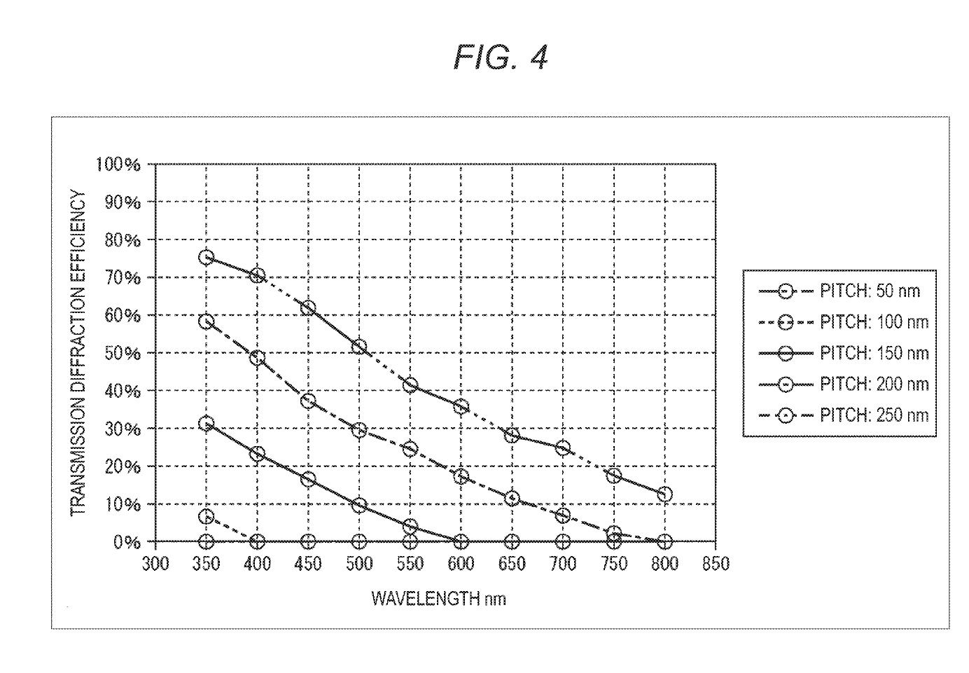

Next, with reference to FIG. 4, transmission diffraction efficiency in the antireflective structure 41 will be described. In FIG. 4, a vertical axis represents the transmission diffraction efficiency whereas a horizontal axis represents a wavelength of incident light.

FIG. 4 illustrates the transmission diffraction efficiency with respect to the wavelength of incident light when light enters perpendicularly to the solid-state imaging element 11 for each pitch of the antireflective structure 41 (50 nm, 100 nm, 150 nm, 200 nm, and 250 nm). Also, the transmission diffraction efficiency represents a proportion of light which is transmitted while being diffracted by the antireflective structure 41 (light that is transmitted with an angle with respect to the incident light) in all the incident light which perpendicularly enters the light incident surface of the semiconductor substrate 21 and is transmitted through the antireflective structure 41.

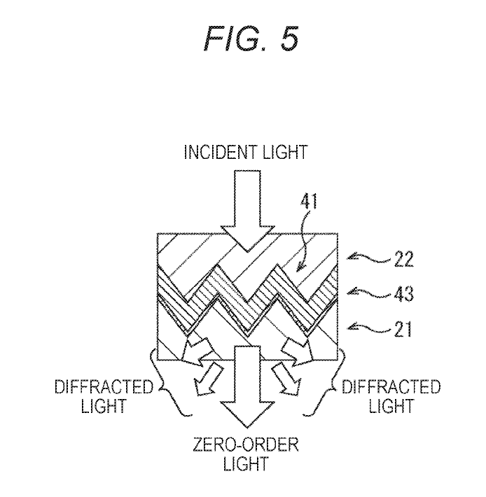

That is, as illustrated in FIG. 5, when the incident light perpendicularly enters the light incident surface of the semiconductor substrate 21, the diffracted light is light that is transmitted while being diffracted by the antireflective structure 41 other than zero-order light that is transmitted through the antireflective structure 41 perpendicularly. Therefore, a total amount of the diffracted light is obtained by subtracting light quantity of the zero-order light that is transmitted through the antireflective structure 41 perpendicularly from the light quantity of all the light that is transmitted through the antireflective structure 41. Note that the light quantity of each order and the light quantity at each angle are different from each other.

As illustrated in FIG. 4, when the pitch of the antireflective structure 41 is larger than 100 nm, considerable light quantity is transmitted while being diffracted, and when the pitch is 100 nm or less, occurrence of the diffracted light is mostly avoided. Therefore, by making the pitch of the anti reflective structure 41 equal to or less than 100 nm, occurrence of diffraction on the light incident surface of the semiconductor substrate 21 can be prevented securely, and a color mixture can be prevented.

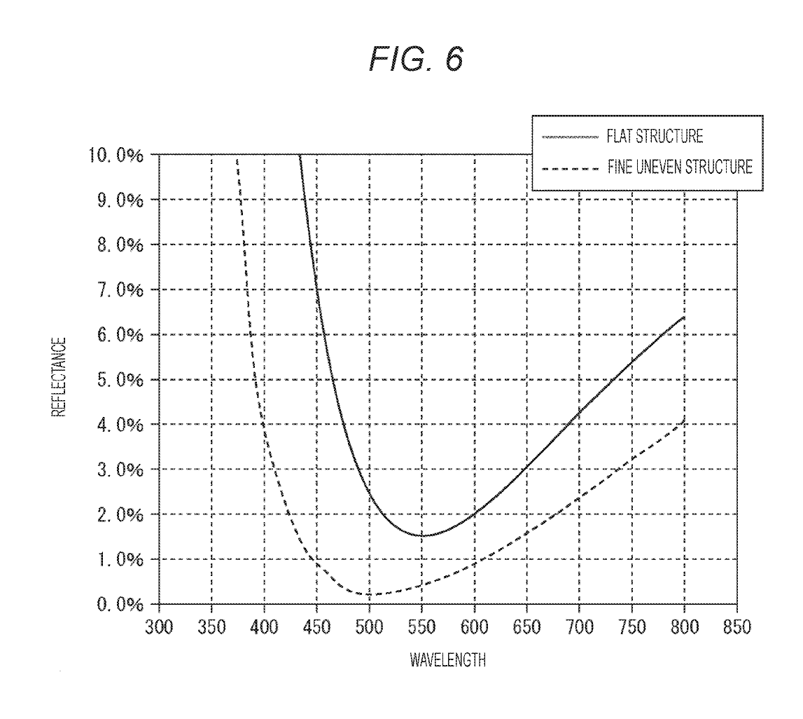

Next, with reference to FIG. 6 to FIG. 8, wavelength dependence of reflectance of the antireflective structure 41 will be described.

FIG. 6 illustrates reflectance in a flat structure in which the light incident surface of the semiconductor substrate is flatly formed as in the conventional solid-state imaging element, and reflectance in the structure in which the fine uneven structure 42 is formed on the light incident surface of the semiconductor substrate 21 as in the solid-state imaging element 11. Note that comparison is made on an assumption that the structure of the dielectric multilayer film lamina ted on the light incident surface of the flat structure is identical to the structure of the dielectric multilayer film laminated in the fine uneven structure 42.

As illustrated in FIG. 6, in the structure in which the fine uneven structure 42 is formed on the light incident surface of the semiconductor substrate 21, reflectance can be reduced in light of all the wavelengths, as compared with the flat structure in which the light incident surface of the semiconductor substrate is formed flatly.

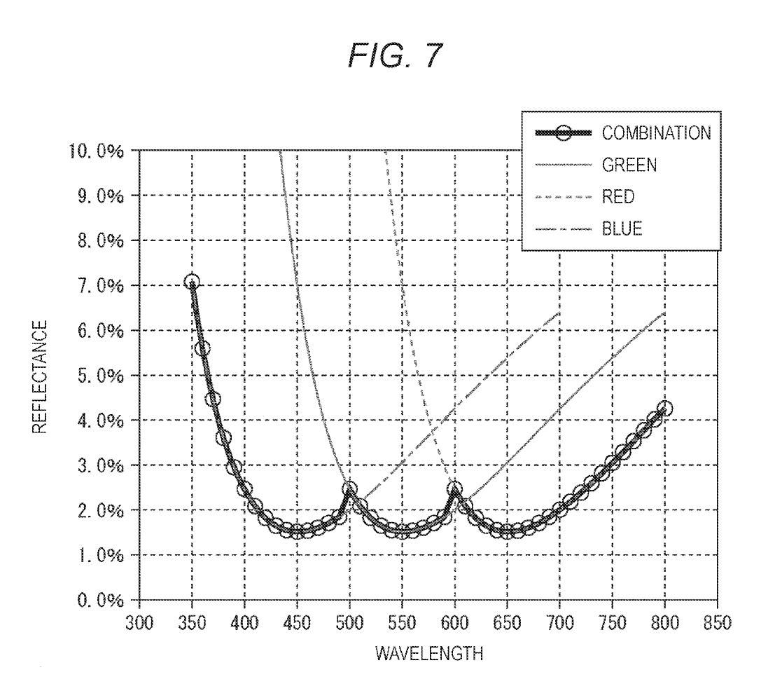

FIG. 7 illustrates, in the flat structure in which the light incident surface of the semiconductor substrate is flatly formed as in the conventional solid-state imaging element, reflectance in the structure in which the structure of the dielectric multilayer film is different for each pixel color as in the dielectric multilayer films 43-1 to 43-3 of FIG. 3.

As illustrated in FIG. 7, in the green pixel, the dielectric multilayer film is formed so that reflectance of about 550-nm light becomes lowest. Similarly, in the red pixel, the dielectric multilayer film is formed so that reflectance of about 650-nm light becomes lowest, and in the blue pixel, the dielectric multilayer film is formed so that reflectance of about 450-nm light becomes lowest.

Also, reflectance of the solid-state imaging element as a whole is a combination of the lowest values of reflectance of green, red, and blue. As illustrated, for example, in a wavelength range of from 400 nm to 700 nm, reflectance has relatively flat values of about 2%, achieving spectrum improvement for each color. Therefore, for example, even for the flat structure in which the light incident surface of the semiconductor substrate is formed flatly, by making the structure of the dielectric multilayer film different for each pixel color, reflectance can be reduced more than in a case where the structure of the dielectric multilayer film is identical in all the pixels. Note that because of the flat structure in which the light incident surface of the semiconductor substrate is formed flatly, occurrence of light diffraction can be inhibited theoretically, and since a process for treatment of the fine uneven structure is unnecessary, the structure can be formed relatively simply.

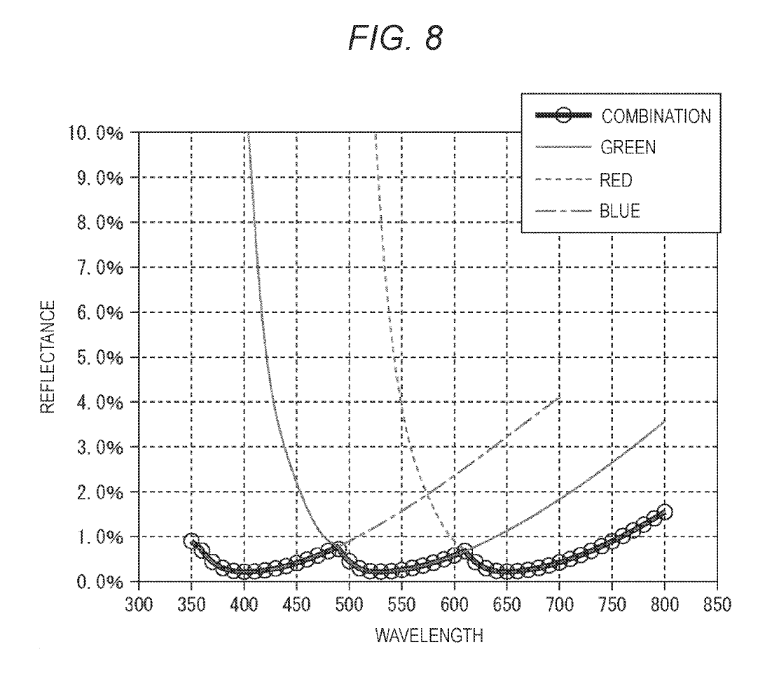

FIG. 8 illustrates, in the structure in which the fine uneven structure 42 is formed on the light incident surface of the semiconductor substrate 21 as in the solid-state imaging element 11, reflectance in the structure in which the structure of the dielectric multilayer film 43 is different for each pixel color.

As illustrated in FIG. 8, in the green pixel, the dielectric multilayer film 43 is formed so that reflectance of about 530-nm light becomes lowest. Similarly, in the red pixel, the dielectric multilayer film 43 is formed so that reflectance of about 650-nm light becomes lowest, and in the blue pixel, the dielectric multilayer film 43 is formed so that reflectance of about 400-nm light becomes lowest.

Also, reflectance of the solid-state imaging element 11 as a whole is a combination of the lowest values of reflectance of green, red, and blue. As illustrated, for example, in the wavelength range of from 400 nm to 700 nm, reflectance has relatively fiat values of about 0.5%, achieving spectrum improvement for each color.

Thus, by providing the fine uneven structure 42 on the light incident, surface of the semiconductor substrate 21 and making the structure of the dielectric multilayer film 43 different for each pixel color, the solid-state imaging element 11 can inhibit reflectance significantly is compared with the flat structure illustrated in FIG. 7

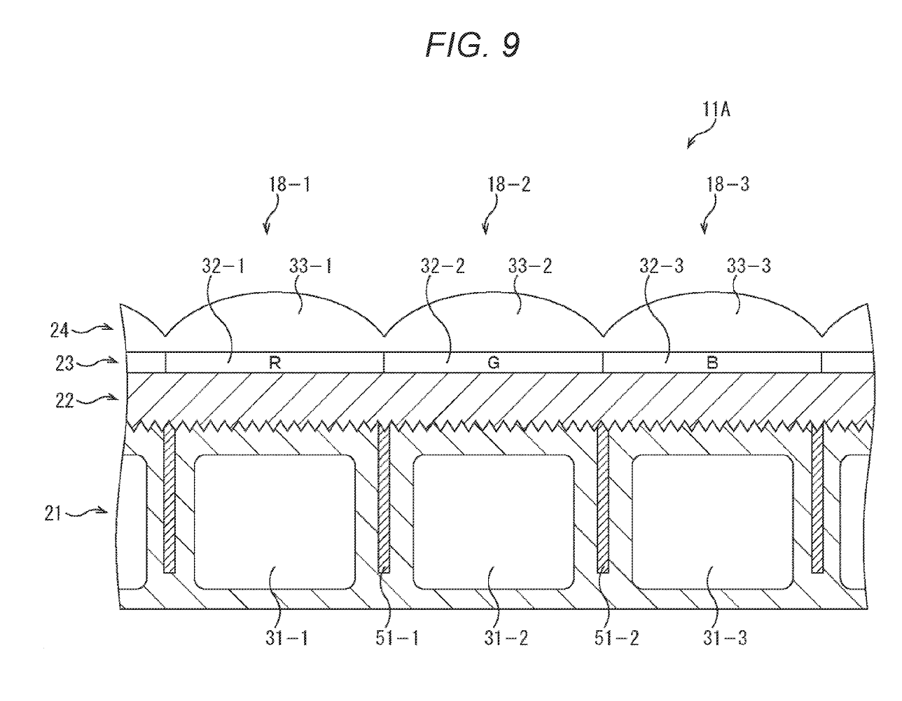

Next, FIG. 9 is a diagram illustrating an exemplary structure of a second embodiment of the solid-state imaging element to which the present technology is applied. In a solid-state imaging element 11A illustrated in FIG. 9, detailed description of the structure that is common to the solid-state imaging element 11 of FIG. 2 will be omitted.

That is, the solid-state imaging element 11A and the solid-state imaging element 11 of FIG. 2 have common structures in which the semiconductor substrate 21, the insulator film 22, the color filter layer 23, and the on-chip lens layer 24 are laminated, and the photoelectric conversion section 31, the filter 32, and the on-chip lens 33 are formed for each pixel 18. Also, although unillustrated in FIG. 9, in the solid-state imaging element 11A, the fine uneven structure 42 is formed on the light incident surface of the semiconductor substrate 21, and the antireflective structure 41 is provided in which the dielectric multilayer flint 43 having the structure different for each pixel 18 is formed, as illustrated in FIG. 3.

Also, in the solid-state imaging element 11A, an inter-pixel light-shielding section 51 having light-shielding properties is formed between the photoelectric conversion sections 31 in the semiconductor substrate 21 so as to separate the adjacent pixels 18. That is, as illustrated in FIG. 9, the inter-pixel light-shielding section 51-1 is formed between the photoelectric conversion section 31-1 and the photoelectric conversion section 31-2, and the inter-pixel light-shielding section 51-2 is formed between the photoelectric conversion section 31-2 and the photoelectric conversion section 31-3.

The inter-pixel light-shielding section 51 is formed by, for example, embedding a light-shielding metal (for example, tungsten) in a trench dug into the semiconductor substrate 21. Thus, by providing the inter-pixel light-shielding section 51, mixing of light from the adjacent pixel 18 can be prevented securely, and occurrence of a color mixture can be avoided.

Note that since design flexibility of the antireflective structure 41 increases by providing the inter-pixel light-shielding section 51, for example, even if the pitch of the fine uneven structure 42 is made larger than 100 nm which results in occurrence of diffracted light, mixing of the diffracted light into the adjacent photoelectric conversion section 31 can be prevented. That is, in the solid-state imaging element 11A, the pitch of the fine uneven structure 42 is not limited to 100 nm or less. This allows further inhibition of light reflection by the antireflective structure 41.

Note that the present technology is applicable to both a front surface irradiation type solid-state imaging element in which a front surface of a semiconductor substrate on which transistor elements or the like are formed is irradiated with incident light, and a back surface irradiation type solid-state imaging element in which a back surface, which is a surface opposite to the front surface, is irradiated with incident light. Also, the present technology is applicable to the solid-state imaging element of both a CMOS image sensor and a CCD.

Note that the solid-state imaging element 11 of each of the above-described embodiments is applicable to various electronic devices, for example, an imaging system, such as a digital still camera and a digital camcorder, a portable telephone having an imaging function, or other devices having an imaging function.

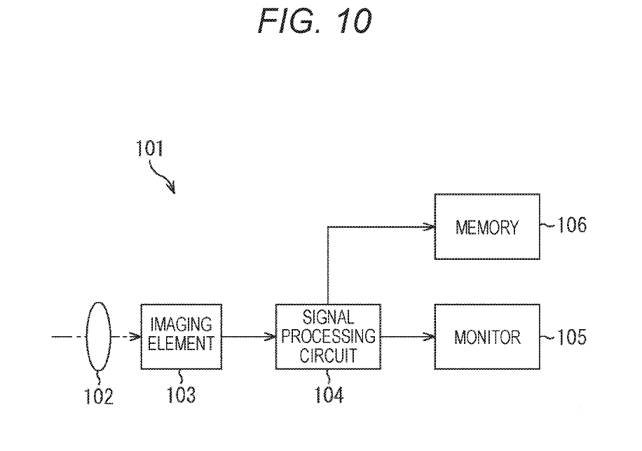

FIG. 10 is a block diagram illustrating an exemplary configuration of an imaging device mounted in an electronic device.

As illustrated in FIG. 10, the imaging device 101 includes an optical system 102, an imaging element 103, a signal processing circuit 104, a monitor 105, and a memory 106, capable of capturing static images and moving images.

The optical system 102 includes one or more lenses, guides image light (incident light) from a subject to the imaging element 103, and then forms an image in a sensor unit of the imaging element 103.

The solid-state imaging element 11 of each of the above-described embodiments is applied to the imaging element 103. In the imaging element 103, electrons are accumulated for a certain period of time in response to the image formed on the light incident surface via the optical system 102. Then, a signal in response to the electrons accumulated in the imaging element 103 is supplied to the signal processing circuit 104.

The signal processing circuit 104 applies various types of signal processing to a pixel signal that is output from the imaging element 103. An image (image data) obtained by the signal processing circuit 104 applying signal processing is supplied to the monitor 105 for display, or is supplied to the memory 106 for storage (recording).

Application of the solid-state imaging element 11 of each of the above-described embodiments allows the imaging device 101 configured in this way, for example, to prevent degradation in image quality caused by occurrence of diffraction on the light incident surface, to achieve low reflection on the light, incident surface, and to capture higher-quality images.

Note that the present technology can have the following structures as well.

(1) A solid-state imaging element including:
a fine uneven structure including a recess and a protrusion which are formed with a predetermined pitch on a light incident surface of a semiconductor layer in which photoelectric conversion sections are formed for a plurality of pixels; and
an antireflective film laminated on the fine uneven structure, the antireflective film being formed with a film thickness different for each color of light received by each of the pixels.

(2) The solid-state imaging element according to (1), wherein the pitch of one of the recess and the protrusion formed in the fine uneven structure is generally identical in all the pixels.

(3) The Solid-state imaging element according to (1) or (2), wherein the pitch of the recess and the protrusion formed in the fine uneven structure is 100 nm or less.

(4) The solid-state imaging element according to any of (1) to (3), further including an inter-pixel light-shielding section having a light-shielding property provided between the adjacent photoelectric conversion sections in the semiconductor substrate.

(5) An electronic device including a solid-state imaging element including:
a fine uneven structure including a recess and a protrusion which are formed with a predetermined pitch on a light incident surface of a semiconductor layer in which photoelectric conversion sections are formed for a plurality of pixels; and
an antireflective film laminated on the fine uneven structure, the antireflective film being formed in film thickness different for each color of light received by each of the pixels.

Note that the present embodiment is not limited to the above-described embodiments, and various changes may be made without departing from the spirit of the present disclosure.

### REFERENCE SIGNS LIST

11 Solid-state imaging element
12 Pixel region
13 Vertical drive circuit
14 Column signal processing circuit
15 Horizontal drive circuit
16 Output circuit
17 Control circuit
18 Pixel
21 Semiconductor substrate
22 Insulator film
23 Color filter layer
24 On-chip lens layer
31 Photoelectric conversion section
32 Filter
33 On-chip lens
41 Antireflective structure
42 Fine uneven structure
43 Dielectric multilayer film
44 Hafnium oxide film
45 Tantalum oxide film
51 Pixel separation section

1-5. (canceled)

6. A solid-state imaging element comprising:
a semiconductor substrate;
a photoelectric conversion region disposed in the semiconductor substrate;
an uneven structure comprising a plurality of recesses and a plurality of protrusions on a light incident surface of the semiconductor substrate, wherein the plurality of protrusions comprise one or more adjacent protrusions;
a hafnium oxide film disposed over the light incident surface of the semiconductor substrate;
a tantalum oxide film disposed over the hafnium oxide film;
an insulating film disposed over the tantalum oxide film;
a color filter disposed over the insulating film; and
a flat surface between the adjacent protrusions.

7. The solid-state imaging element according to claim 6, wherein each recess of the plurality of recesses comprises a flat surface.

8. The solid-state imaging element according to claim 6, wherein a pitch of the plurality of recesses and the plurality of protrusions is 100 nm or less.

9. The solid-state imaging element according to claim 6, further comprising an inter-pixel light-shielding section having a light-shielding property provided between adjacent photoelectric conversion sections in the semiconductor substrate.

10. The solid-state imaging element of claim 6, wherein each of the one or more adjacent protrusions are separated by one of the plurality of recesses.

11. The solid-state imaging element of claim 6, wherein a thickness of one or more of the hafnium oxide film and the tantalum oxide film is determined based on a wavelength of a color associated with the color filter.

12. The solid-state imaging element of claim 6, wherein the insulator film comprises silicone dioxide.

13. An electronic device comprising a solid-state imaging element comprising:
a semiconductor substrate;
a photoelectric conversion region disposed in the semiconductor substrate;
an uneven structure comprising a plurality of recesses and a plurality of protrusions on a light incident surface of the semiconductor substrate, wherein the plurality of protrusions comprise one or more adjacent protrusions;
a hafnium oxide film disposed over the light incident surface of the semiconductor substrate;
a tantalum oxide film disposed over the hafnium oxide film;
an insulating film disposed over the tantalum oxide film;
a color filter disposed over the insulating film; and
a flat surface between the adjacent protrusions.

14. The electronic device according to claim 13, wherein each recess of the plurality recesses comprises a flat surface.

15. The electronic device according to claim 13, wherein a pitch of the plurality of recesses and the plurality of protrusions is 100 nm or less.

16. The electronic device according to claim 13, further comprising an inter-pixel light-shielding section having a light-shielding property provided between adjacent photoelectric conversion sections in the semiconductor substrate.

17. The electronic device according to claim 13, wherein each of the one or more adjacent protrusions are separated by one of the plurality of recesses.

18. The electronic device according to claim 13, wherein a thickness of one or more of the hafnium oxide film and the tantalum oxide film is determined based on a wavelength of a color associated with the color filter.

19. The electronic device according to claim 13, wherein the insulator film comprises silicone dioxide.

20. A method of forming a solid-state imaging element, the method comprising:
disposing a photoelectric conversion region in a semiconductor substrate, wherein a light incident surface of the semiconductor substrate comprises an uneven structure comprising a plurality of recesses and a plurality of protrusions, wherein the plurality of protrusions comprise one or more adjacent protrusions, wherein the plurality of recesses comprise a flat surface between the one or more adjacent protrusions;
disposing a hafnium oxide film over the light incident surface of the semiconductor substrate;
disposing a tantalum oxide film over the hafnium oxide film;
disposing an insulating film over the tantalum oxide film; and
disposing a color filter over the insulating film.

21. The method according to claim 20, wherein each recess of the plurality recesses comprises a flat surface.

22. The solid-state imaging element according to claim 20, wherein a pitch of the plurality of recesses and the plurality of protrusions is 100 nm or less.

23. The solid-state imaging element according to claim 20, further comprising providing an inter-pixel light-shielding section having a light-shielding property between adjacent photoelectric conversion sections in the semiconductor substrate.

24. The solid-state imaging element of claim 20, wherein each of the one or more adjacent protrusions are separated by one of the plurality of recesses.

25. The solid-state imaging element of claim 20, wherein a thickness of one or more of the hafnium oxide film and the tantalum oxide film is determined based on a wavelength of a color associated with the color filter.
